(19) United States
(12) Patent Application Publication
(10) Pub. No.: US 2012/0114976 A1
(43) Pub. Date: May 10, 2012

(54) Sputtering targets and recording materials of the magnetic recording medium formed from the same

(75) Inventors: Sheang-Hsien Rou, Tainan (TW); Wen-Tsang Liu, Tainan (TW); Shou-Hsien Lin, Tainan (TW)

(73) Assignee: Solar Applied Materials Technology Corp, Tainan (TW)

(21) Appl. No.: 13/273,420

(22) Filed: Oct. 14, 2011

(30) Foreign Application Priority Data
Nov. 5, 2010 (TW) 099138115

(51) Int. Cl. G11B 5/64; C23C 14/08; C23C 14/34

(52) U.S. Cl. 428/826; 204/298.13

(57) ABSTRACT

The present invention provides a sputtering target essentially consisting of cobalt-platinum-copper oxide-oxide (CoPt—CuO-oxide), cobalt-chrome-platinum-copper oxide-oxide (CoCrPt—CuO-oxide), or cobalt-chrome-platinum-boron-copper oxide-oxide (CoCrPtB—CuO-oxide) with addition of CuO. The sputtering target is applied to a recording material of a magnetic recording medium. The thickness of the oxide grain boundary in the sputtering target is reduced, resulting from the decreased amount of oxide in the sputtering target, to allow a sputtering process utilizing the same to become more stable. Further, the volume of the magnetic grains per unit area is increased, whereby a better thermal stability and a high recording density are acquired.

### BACKGROUND OF THE INVENTION

1. Field of the Invention

The present invention relates to a sputtering target, and also relates to a recording material of magnetic recording medium formed from the sputtering target.

2. Description of Related Art

The conventional magnetic recording techniques of a hard disk are classified into two categories according to the orientation of magnetization: longitudinal magnetic recording and perpendicular magnetic recording. In longitudinal magnetic recording, the magnetic flux is aligned longitudinal to the surface of the disk, whereas in perpendicular magnetic recording, the magnetic flux is aligned perpendicular to the surface of the disk. As shown in FIG. 1, a current perpendicular magnetic recording medium consists of a substrate (glass or Aluminum), an adhesive layer, a soft underlayer, a seed layer, an intermediate layer, a recording layer, a covering layer and a lubricative layer, wherein the most critical technique lies in manufacturing the recording layer.

As shown in FIG. 2, in IEEE Trans. Magn., 38 (2002) 1976 disclosed is that adding oxides into the very thin Co—Pt based magnetic recording layer can effectively make the oxides segregate at the grain boundary without destroying the grain structure of the Co-based magnetic grains, including the Hexagonal Close Packed (HCP) and c-axis orientation and thereby the grain size is reduced to less than 10 nm and the signal-to-noise ratio is raised.

As mentioned above, a microstructure with granular magnetic thin film with good magnetic properties, high thermal stability and good recording performance can be obtained by addition of oxides, which renders the high-density perpendicular recording media achievable. As shown in FIG. 1, the conventional recording layer of a hard disk consists of multiple layers, the first layer directly above the intermediate layer is called Mag.1, and the subsequent upper layers in sequence are the second layer (Mag.2), the third layer (Mag.3), and so on. The Mag.1 has a structure that ferromagnetic grains are uniformly distributed within the oxides, such that the nonmagnetic oxides can cause good magnetic isolation of the magnetic crystal grains and reduce the noise in the recording media.

As shown in FIG. 3, Appl. Phys. Lett. 95:102507 (2009) discloses that a single oxide layer in magnetic recording thin film can achieve an effective magnetic isolation. On the contrary, the conventional magnetic recording layer requires an oxide grain boundary (GB.) that is thicker than 1 nm to reach such an effective isolation of magnetic exchange coupling. It is suggested that the oxide grain isolating magnetic exchange coupling in the magnetic recording thin film contains partially a weak-magnetic Co-A-O compound, wherein A is an element selected from the group consisting of Si, Ti, Ta, Cr, Nb, Hf, Zr, W and Y. In such a way, the thickness of oxide grain boundary (GB.) in the conventional recording layer needs to be greater than 1 nm to diminish the magnetic coupling; however, some other problems still remain to be resolved as set forth below:

1. An increased amount of oxides is added for obtaining an effective isolation of magnetic grains to reduce noise. However, excessive oxide will diffuse into magnetic grains and increase the noise instead of reducing the noise.

2. In the sputtering process, the excessive oxide may easily cause arcing on a portion of the surface of the target to affect the sputtering process and cause low quality of the thin-film.

Further, the US patent publication US2006286414A1 discloses that a sputtering target for use in producing a recording layer of hard disks comprises CoPt-oxide, CoCrPt-oxide or CoCrPtB-oxide and an elemental metal additive that is substantially insoluble in Co and has a reduction potential greater than −0.03 eV, wherein the elemental metal additive is Cu, Ag, or Au. However, said patent publication only refers to Cu element but is completely silent to use of CuO as the additive to the target.

Although the above references disclose that adding a proper amount of additives can reduce the magnetic exchange coupling and increase the signal-to-noise ratio, none of the sputtering target or the recording material of magnetic recording media disclosed by the references avoids the problems that are caused by excessive oxide during the sputtering process and is effective on reducing the thickness of oxide GB. in the recording layer. To mitigate or obviate the aforementioned problems, the present invention provides a sputtering target without containing excess of oxides, and recording materials in magnetic recording medium formed from the sputtering target that performs an ideal signal-to-noise ratio.

### SUMMARY OF THE INVENTION

Given the problems of the conventional targets as described above, the objective of the present invention is to provide a sputtering target and a recording material of magnetic recording media formed from the sputtering target which uses CuO as an additive to the sputtering target to obtain a recording layer of the magnetic recording media with improved signal-to-noise ratio and enhanced areal recording density for further expanding data storage capacity of recording media.

Accordingly, the present invention provides a sputtering target, which comprises CoPt, CoCrPt or CoCrPtB-based alloy and an oxide combination, wherein the oxide combination includes copper oxide (CuO) and at least one oxide selected from the group consisting of titanium dioxide (TiO₂), chromium oxide (Cr₂O₃), tantalum oxide (Ta₂O₅), niobium oxide (Nb₂O₅), yttrium oxide (Y₂O₃), zirconium oxide (ZrO₂) and hafnium oxide (HfO₂). The sputtering target is prepared by the following steps:

forming a prealloy by mixing raw materials of CoPt, CoCrPt or CoCrPtB based alloy as described above;

processing the prealloy to generate prealloy powder; mixing the prealloy powder with the combination of oxides; alternatively, mixing the prealloy powder with additional element(s); or alternatively, mixing the prealloy powder with a mixture of the prealloy powder and the oxide combination, to form a powder mixture; and

sintering the powder mixture to form the sputtering target.

Preferably, the oxide combination in the sputtering target further comprises silicon oxide.

In another aspect, the present invention also provides a recording material of magnetic recording medium, which is formed from sputtering the sputtering target onto a surface.

Preferably, the recording material of the magnetic recording medium is applied to a recording layer of a hard disk.

Preferably, the recording material of a magnetic recording medium is applied to perpendicular magnetic recording media.

The present invention provides a sputtering target comprising an additive CuO and is applied to form a recording material of magnetic recording media that is accompanied by the following advantages and improvements.

The thickness of the oxide grain boundary is reduced, which results from the decrease of the amount of oxide in the sputtering target and allows a sputtering process utilizing the same to become more stable. Further, the volume of the magnetic grains per unit area is relatively increased, resulting in a better thermal stability and a high recording density of the whole recording media.

### BRIEF DESCRIPTION OF THE DRAWINGS

FIG. 1 is an illustrative scheme of the structure of the conventional perpendicular magnetic recording media;

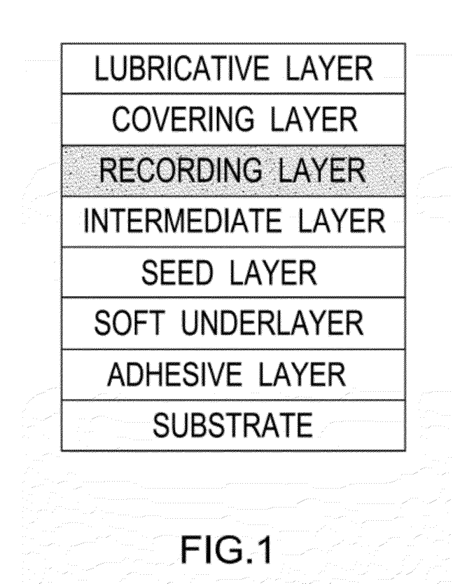

FIG. 2 illustrates a microstructure of the CoPtCr-oxide thin-film shown under Transmission Electron Microscope (TEM) in IEEE Trans. Magn., 38:1976 (2002); and

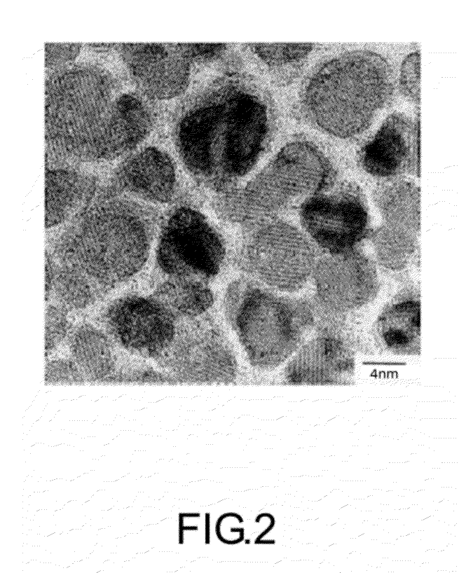

FIG. 3 illustrates a structure of the conventional recording layer without adding CuO; and

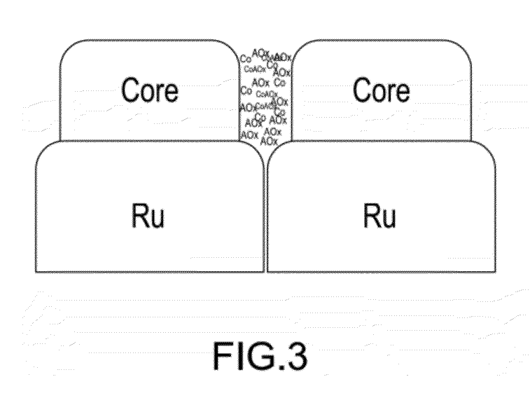

FIG. 4 illustrates a structure of a recording layer of the present invention with additive CuO.

### DETAILED DESCRIPTION OF PREFERRED EMBODIMENT

In the following description of the preferred embodiment, reference is made to the accompanying drawings that form a part thereof, and in which is shown by way of illustration of a specific embodiment in which the invention may be practiced. It is to be understood that other embodiments may be utilized and changes may be made without departing from the scope of the present invention.

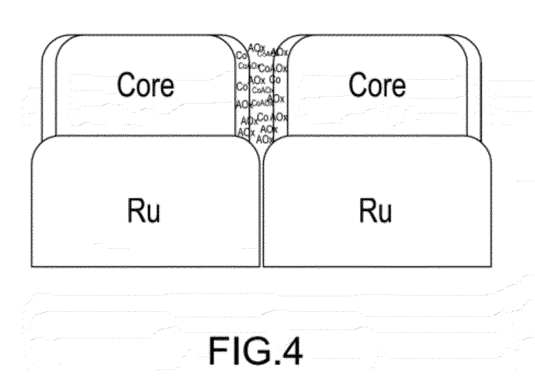

FIG. 4 illustrates a structure of a recording layer of the present invention obtained from the sputtering target containing CuO.

A recording material of a magnetic recording medium in accordance with the present invention essentially consists of CoPt or CoCrPt or CoCrPtB based alloy and an oxide combination, wherein the oxide combination includes copper oxide (CuO) and at least one oxide selected from the group consisting of titanium dioxide (TiO₂), chromium oxide (Cr₂O₃), tantalum oxide (Ta₂O₅), niobium oxide (Nb₂O₅), yttrium oxide (Y₂O₃), zirconium oxide (ZrO₂) and hafnium oxide (HfO₂). The recording material in the magnetic recording medium is prepared by using the sputtering target in accordance with the present invention in a sputtering process. The sputtering target essentially consists of CoPt or CoCrPt or CoCrPtB based alloy and an oxide combination, wherein the oxide combination includes copper oxide (CuO) and at least one oxide selected from the group consisting of titanium dioxide (TiO₂), chromium oxide (Cr₂O₃), tantalum oxide (Ta₂O₅), niobium oxide (Nb₂O₅), yttrium oxide (Y₂O₃), zirconium oxide (ZrO₂) and hafnium oxide (HfO₂).

The sputtering target is prepared by the following steps:

forming a prealloy by mixing raw materials of CoPt, CoCrPt or CoCrPtB-based alloy as previously described;

processing the prealloy to generate prealloy powder;

mixing the prealloy powder with the oxide combination as described above; alternatively, mixing the prealloy powder with additional element(s); or alternatively, mixing the prealloy powder with a mixture of the prealloy powder and the oxide combination, to form a powder mixture; and

sintering the powder mixture to form the sputtering target.

In a preferred embodiment, the oxide combination in the sputtering target further comprises silicon oxide.

A recording material of a magnetic recording medium in accordance with the present invention is formed by sputtering the sputtering target onto a surface.

The recording material of the magnetic recording medium is applied to a recording layer of a hard disk.

The recording material of the magnetic recording medium is formed by the conventional sputtering methods, including but not limited to, ion beam sputtering, plasma sputtering deposition and the like.

In a preferred embodiment of the present invention, the recording material is obtained by the following steps: providing a substrate (such as glass or Aluminum) with deposited layers including an adhesive layer, a soft underlayer, a seed layer, an intermediate layer as in the perpendicular magnetic recording medium, and sputtering the sputtering target directly onto the intermediate layer to form a recording layer under Argon (Ar) gas in a chamber.

The recording material, a thin film, is formed by sputtering the CuO-containing or non-CuO-containing targets onto a surface of a substrate, and then subjected to vibrating sample magnetometer (VSM) to measure the values of the coercivity (Hc) and the nucleation field (Hn) of the thin film formed from the sputtering targets, and the normalized value of exchange decouple [(Hc-Hn)/Hc] was calculated accordingly.

TABLE 1

| Component (atomic percentage, at. %) | | | | | | | | | |
|---|---|---|---|---|---|---|---|---|---|
| | | | Silica | Titanium | Chromium | Copper | | Nucleation | |
| Cobalt | Chromium | Platinum | oxide | oxide | oxide | oxide | Coercivity | field | |
| (Co) | (Cr) | (Pt) | (SiO₂) | (TiO₂) | (Cr₂O₃) | (CuO) | (Hc (Oe)) | (Hn (Oe)) | (Hc − Hn)/Hc |
| Balance | 7.12 | 17.8 | 6 | 4 | 1 | 0 | 5102 | 2464 | 0.517 |
| | 5.34 | 17.8 | 6 | 4 | 1 | 3.56 | 4990 | 2218 | 0.556 |
| | 7.2 | 18 | 4 | 2 | 4 | 0 | 5263 | 2625 | 0.501 |
| | 5.4 | 18 | 4 | 2 | 4 | 3.6 | 5060 | 2354 | 0.535 |

As shown in Table 1, in the thin film formed from the sputtering target containing CuO, SiO₂ functions as the glass former to form a compact grain boundary layer with a smoother surface, and oxides, such as TiO₂ and Cr₂O₃, have a propensity to bond to CuO. Therefore, the concentration of Co is reduced in the oxide grain boundary layer and thus an effective isolation of magnetic grains is obtained. As shown in Table 1, the thin films formed from the sputtering targets containing the same atomic % of silicon oxide (SiO₂), titanium dioxide (TiO₂) and chromium oxide (Cr₂O₃) in presence with CuO have a higher normalized value of exchange decouple [(Hc—Hn)/Hc], which indicates that adding CuO to the sputtering target indeed disrupts the magnetic exchange coupling.

As mentioned in the above-cited references, the thickness of the oxide grain boundary in the recording layer has to be greater than 1 nm to achieve an effective magnetic decoupling. The present invention provides a sputtering target for resolving the above-mentioned problems, wherein the sputtering target is characterized by:

(1) The elements or the oxides thereof are provided as X, X—O and X-A-O, the elements and the oxides thereof are substantially insoluble in Co or do not easily form a compound with Co, wherein X does not belong to the element Co or Pt; and preferably, X is Cu; wherein A is an element selected from the group consisting of Ti, Cr, Ta, Nb, Y, Zr, and Hf;

(2) The Gibbs free energy of X-A-O is lower than that of Co-A-O, which causes easy forming of X-A-O and acquiring a higher stability than that of Co-A-O, which is beneficial to the subsequent procedures; and

(3) X-A-O is either paramagnetic or diamagnetic, i.e., non-ferromagnetic, promoting magnetic decoupling and segregation in the oxide G.B. in the recording layer, and thus an enhanced signal-to-noise ratio is obtained without use of extra oxide.

Table 2 demonstrates the reactivity between indicated oxides to form a new oxide compound. The amounts of the elements Cu, Ag, and Au dissolved in Co are little, wherein only Cu—O is easier to form a compound with A-O. Neither Ag—O nor Au—O can form a stable compound with A-O. As a result, Cu—O is selected to add to an original CoPt-oxide to facilitate the subsequent procedures. By the propensity of A-O to bond to CuO, the concentration of Co in the oxide G.B. was reduced and a good isolation of magnetic grains of recording layer was obtained.

TABLE 2

| | CuO | AgO | AuO |
|---|---|---|---|
| SiO₂ | X | X | X |
| TiO₂ | Ti₃Cu₃O | X | X |
| | Ti₄Cu₂O | | |
| Cr₂O₃ | CuCr₂O₄ | Ag₂CrO₄ | X |
| | Cu₂Cr₂O₄ | | |
| Ta₂O₅ | Cu₂Ta₄O₁₁ | X | X |
| | Cu₇Ta₁₅O₄₁ | | |
| | Cu₅Ta₁₁O₃₀ | | |
| | Cu₃Ta₇O₁₉ | | |
| Nb₂O₅ | Cu₃Nb₂O₈ | X | X |
| | CuNb₂O₆ | | |
| Y₂O₃ | Cu₂Y₂O₅ | X | X |

The present invention is based on the following aspects. The Gibber free energy of the copper-based oxide, such as Cu—Ti—O, Cu—Ta—O, Cu—Cr—O, Cu—Nb—O and Cu—Y—O, is lower than that of the cobalt-based oxide, such as Co—Ti—O, Co—Ta—O, Co—Cr—O, Co—Nb—O and Co—Y—O. The copper-based oxides are paramagnetic or diamagnetic. Therefore, the present invention is characterized by addition of CuO in the sputtering target in a form of CoPt—CuO—TiO₂, CoPt—CuO—Ta₂O₅, CoPt—CuO—Nb₂O₅, CoPt—CuO—Cr₂O₃ or CoPt—CuO—Y₂O₃ and for producing the recording material of a magnetic recording medium in accordance with the present invention.

As shown in Table 2, a sputtering target with CoPt-based alloy further comprising Cr or B atoms was also provided, which was the sputtering target consisting of CoPt-based alloy, CoCrPt-based alloy or CoCrPtB-based alloy and an oxide combination including copper oxide (CuO) and at least one oxide selected from the group consisting of titanium dioxide (TiO₂), chromium oxide (Cr₂O₃), tantalum oxide (Ta₂O₅), niobium oxide (Nb₂O₅), yttrium oxide (Y₂O₃), zirconium oxide (ZrO₂) and hafnium oxide (HfO₂).

As shown in FIG. 4, Cu atom in the sputtering target containing CuO as mentioned above repels Co atom back to magnetic grains or prevents Co atom from forming compound with A-O. Therefore, magnetic decoupling and segregation of oxides in the oxide grain boundaries in the thin film is greatly promoted, whereby the signal-to-noise ratio of the recording material of the magnetic recording medium is enhanced without excessive oxide.

Accordingly, the sputtering target in accordance with the present invention utilizes CuO in a sputtering process for forming the recording material of a magnetic recording medium in accordance with the present invention is accompanied by the following advantages and improvements:

The thickness of the oxide grain boundary is reduced, suggesting that the amount of oxide in the sputtering target is decreased, such that the sputtering process utilizing the same becomes more stable than the conventional process. Moreover, the volume of the magnetic grains per unit area is relatively increased, and a better thermal stability and a high recording density are thus acquired.

Even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A sputtering target, which comprises CoPt or CoCrPt or CoCrPtB based alloy and an oxide combination, wherein the oxide combination includes copper oxide (CuO) and at least one oxide selected from the group consisting of titanium dioxide (TiO₂), chromium oxide (Cr₂O₃), tantalum oxide (Ta₂O₅), niobium oxide (Nb₂O₅), yttrium oxide (Y₂O₃), zirconium oxide (ZrO₂) and hafnium oxide (HfO₂).

2. The sputtering target as claimed in claim 1, wherein the oxide combination further comprises silicon oxide (SiO₂).

3. A recording material of a magnetic recording medium, which is formed by sputtering the said sputtering target as claimed in claim 1.

4. The recording material of a magnetic recording medium of claim 3, wherein the oxide combination further comprises silicon oxide (SiO₂).

5. The recording material of the magnetic recording medium as claimed in claim 4, which is applied to a recording layer of a hard disk.

6. The recording material of the magnetic recording medium as claimed in claim 4, which is applied to perpendicular magnetic recording media.
